(19) United States
(12) Patent Application Publication
(10) Pub. No.: US 2006/0159291 A1
(43) Pub. Date: Jul. 20, 2006

(54) Portable multi-functional audio sound system and method therefor

(76) Inventors: Richard H. Fliegler, Fountain Hills, AZ (US); Charles C. Adams, Gilbert, AZ (US); Keith L. Chapman, Fountain Hills, AZ (US); Dale V. Curtis, Scottsdale, AZ (US); Shane A. Nicholas, Anthem, AZ (US); Shawn R. Greene, Higley, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 11/036,505

(22) Filed: Jan. 14, 2005

(51) Int. Cl. G10H 1/00; H03F 21/00

(52) U.S. Cl. 381/118; 381/120

(57) ABSTRACT

A portable multi-functional audio sound system has an enclosure and control panel with an optional display on a front portion of the enclosure. The control panel provides for selection among menu options which are presented on the display. An audio input is coupled for receiving a live audio signal. An electronic circuit receives user commands from the control panel and displays configuration information on the display. The electronic circuit has an amplifier for amplifying the live audio signal, and a synthesizer for generating programmable audio signal in response to a MIDI data stream. The MIDI data stream is routed to the digital signal processor or to the synthesizer. A digital signal processor controls the menu options on the display. A speaker is mounted within the enclosure and coupled for receiving a combined signal of the live audio signal and the programmable audio signal.

### FIELD OF THE INVENTION

The present invention relates in general to audio sound systems and, more particularly, to a portable multi-functional audio sound system.

### BACKGROUND OF THE INVENTION

Audio sound systems are commonly used to amplify signals and produce audible sound. A sound generation source, such as a musical instrument, microphone, CD player, or other electronic device, generates the electrical audio signal. The audio signal is routed to an audio amplifier, which increases the magnitude of the audio signal. The audio amplifier can also perform filtering, modulation, distortion enhancement or reduction, sound effects, and other signal processing functions to enhance the tonal quality and properties of the signal. The amplified audio signal is sent to a speaker to convert the electrical signal to audible sound and reproduce the original sound from the sound generation source.

Musical instruments have always been very popular in society providing entertainment, social interaction, self-expression, and a business and source of livelihood for many people. String instruments are especially popular because of their active playability, tonal properties, and portability. String instruments are fun and yet challenging to play, have great sound qualities, and are easy to move about from one location to another.

In one example, the sound generation source may be an electric guitar or electric bass guitar, which are well-known musical instruments. The guitar has an audio output which is connected to an audio amplifier. The output of the audio amplifier is connected to a speaker to generate audible musical sounds. In some cases, the audio amplifier and speaker are separate units. In other systems, the units are integrated into one chassis. The integrated system may be portable in some applications.

The electric guitar requires an audio amplifier to function. Other guitars use the amplifier to enhance the sound. The guitar audio amplifier provides features such as amplification, filtering, tone equalization, and sound effects. The user adjusts the knobs on the front panel of the audio amplifier to dial in the desired volume, acoustics, and sound effects.

However, most if not all audio amplifiers are limited in the features that each can provide. High-end amplifiers provide more in the way of high quality sound reproduction and a variety of signal processing options, but are generally expensive and difficult to transport. The speaker is typically a separate unit from the amplifier in the high-end gear. Low-end amplifier may be more affordable and portable, but have limited sound enhancement features. There are few amplifiers for the low to medium end consumer market which provide full features, easy transportability, and are inexpensive.

A need exists for a portable, fully integrated, multi-functional audio sound system with a wide range of features to meet the needs and desires of the low to medium end user.

### SUMMARY OF THE INVENTION

In one embodiment, the present invention is an audio sound system comprising an enclosure for providing structural support. A control panel has a display on a front portion of the enclosure. An audio input is coupled for receiving a live audio signal. An electronic circuit is disposed within the enclosure and receives user commands from the control panel and displays configuration information on the display. The electronic circuit has an amplifier for amplifying the live audio signal, and a synthesizer for generating a programmable audio signal in response to a data stream. A speaker is mounted within the enclosure and coupled for receiving a combined signal of the live audio signal and the programmable audio signal.

In another embodiment, the present invention is a transportable audio sound system comprising an enclosure for providing structural support. A control panel is disposed on a portion of the enclosure. An audio input is coupled for receiving an audio signal. An electronic circuit receives commands from the control panel. The electronic circuit has an amplifier for amplifying the audio signal, and a synthesizer for generating a programmable audio signal in response to a data stream. A speaker is mounted within the enclosure and coupled for receiving the audio signal and the programmable audio signal.

In another embodiment, the present invention is an audio sound system comprising an enclosure having a control panel and an audio input coupled for receiving an audio signal. An amplifier amplifies the audio signal. A synthesizer generates a programmable audio signal in response to a data stream. A speaker is mounted within the enclosure and receives the audio signal or the programmable audio signal.

In another embodiment, the present invention is a method of providing signal processing features for an audio sound system comprising providing an enclosure having a control panel and an audio input coupled for receiving an audio signal, amplifying the audio signal, synthesizing a data stream to generate a programmable audio signal, and providing a speaker mounted within the enclosure for receiving the audio signal or the programmable audio signal.

In another embodiment, the present invention is an audio sound system comprising an enclosure having a control panel and an audio input coupled for receiving an audio signal. A synthesizer is within the enclosure for generating a programmable audio signal in response to a data stream. A digital signal processor is within the enclosure providing at least one feature selected from the group consisting of equalizer, fully chromatic tuner, phrase sampler, phrase trainer, play loops, MIDI files, variable speed playback, sample recording, sound selection, and style selection. A speaker is mounted within the enclosure and coupled for receiving the audio signal or the programmable audio signal.

### BRIEF DESCRIPTION OF THE DRAWINGS

FIG. 1 illustrates a guitar connected to an audio sound system;

FIG. 2 illustrates a front view of the audio sound system;

FIG. 3 illustrates further detail of the control panel of the audio sound system;

FIG. 4 illustrates the LCD display in a first operating mode;

FIG. 5 illustrates the LCD display in a second operating mode;

FIG. 6 illustrates a prospective view of the audio sound system;

FIG. 7 illustrates a back view of the audio sound system;

FIG. 8 illustrates an electrical block diagram of the audio amplifier and speaker system; and

FIGS. 9a-9c illustrate representative configurations of the electrical block diagram of FIG. 8.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

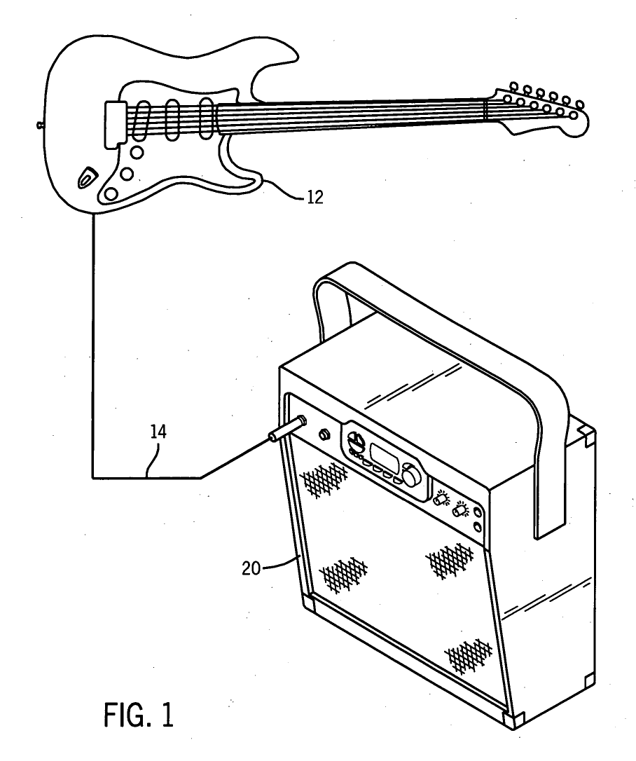

Referring to FIG. 1, a musical instrument such as electric guitar 12 is shown with an audio output cable 14. In other embodiments, the musical instrument may be an electric bass guitar, violin, horns, brass, drums, wind instruments, string instruments, electric keyboard, audio microphone, percussions, or other instrument generating electric signals representative of sound content. Guitar 12 generates an electric signal representative of the produced sounds, which is sent to audio sound system 20 for signal conditioning and power amplification. Audio sound system 20 includes an audio amplifier and speaker system. The signal conditioning may include amplification, equalization, filtering, special effects, and other signal processing. The power amplification increases the power level and signal strength of the audio signal to drive the speaker system and reproduce the original sound generated by guitar 12.

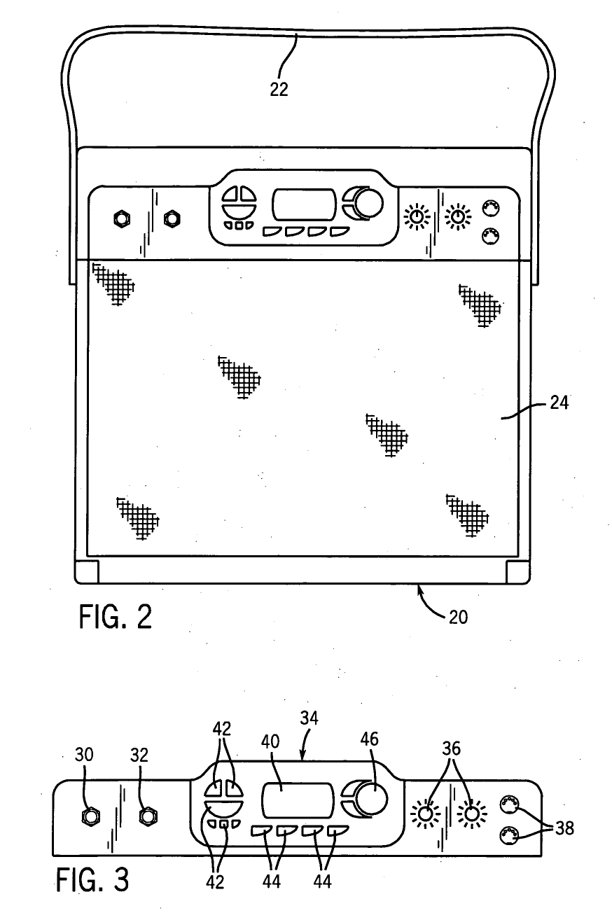

Turning to FIG. 2, a front view of audio sound system 20 is shown. As an initial observation, the form factor and foot print of audio sound system 20 is designed for portable use and easy transportability. Audio sound system 20 measures about 13 inches high, 15 inches wide, and 7 inches deep, and weights about 16 pounds. A carry handle or strap 22 is provided to support the portability and ease of transport features. Audio sound system 20 has an enclosure defined by an aluminum folded chassis, wood cabinet, black vinyl covering, front control panel, and cloth grille over speaker area 24. Audio sound system 20 has a front control panel with connections for audio input, headphone, control buttons and knobs, liquid crystal display (LCD), and Musical Instrument Digital Interface (MIDI) input/output (I/O) jacks.

Further detail of the front control panel of audio sound system 20 is shown in FIG. 3. The external features of audio sound system 20 include audio input jack 30 for connecting to guitar 12 or other musical instruments, headphone jack 32 for connecting to external headphones (not shown), control panel 34, control knobs 36, and MIDI I/O jacks 38. Control knobs 36 are provided in addition to control panel 34 for audio control functions which are frequently accessed by the user. In the present embodiment, control knobs 36 provide user control of volume and tone. In other embodiments, additional control knobs 36 may control frequency response, equalization, and other sound control functions.

Control panel 34 includes LCD 40, functional mode buttons 42, selection buttons 44, and adjustment knob or data wheel 46. The functional mode buttons 42 and selection buttons 44 are elastomeric rubber pads for soft touch and long life. Alternatively, the buttons may be hard plastic with tactic feedback micro-electronic switches. Audio sound system 20 is fully programmable, menu driven, and uses software to configure and control the sound reproduction features. The combination of functional mode buttons 42, selection buttons 44, and data wheel 46 provide control for the user interface over the different operational modes, access to menus for selecting and editing functions, and configuration of the audio sound system. The front panel of audio sound system 20 may also include LEDs as indicators for sync/tap, tempo, save, record, and power functions.

In general, control panel 34 is the user interface to the fully programmable, menu driven configuration and control of the electrical functions within the audio sound system. LCD 40 changes with the user selections to provide many different configuration and operational menus and options. The operating modes may include startup and self-test, play, edit, utility, save, and tuner. In one operating mode, LCD 40 may show the playing mode of the audio sound system. In another operating mode, LCD 40 may display the MIDI data transfer in process. In another operating mode, LCD 40 may display default setting and presets. In yet another operating mode, LCD 40 may display a tuning meter.

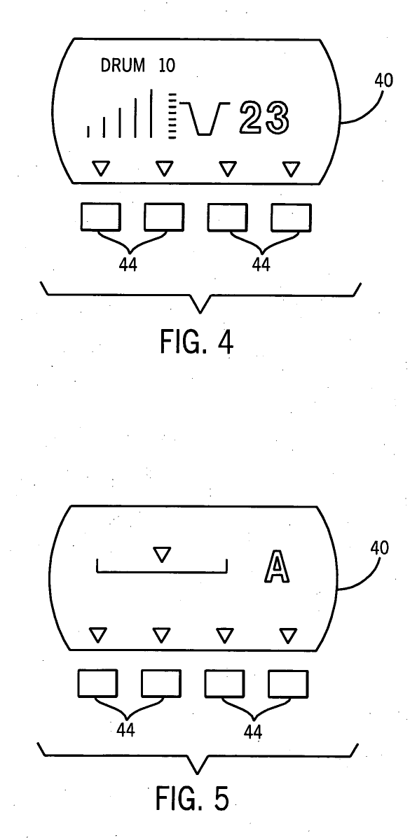

FIG. 4 illustrates LCD 40 in one operating mode. The LCD can display information such as bar meters, alphanumeric data for accompanying instruments, graphic information for frequency response, and numbers for volume levels. The bottom part of LCD 40 shows arrows pointing to selection keys 44. The selection keys can be programmed to perform different functions which are dynamically assigned to the selection keys and identified on the LCD. The software executing within audio sound system 20 controls LCD 40 to display many different menu and submenu levels in a hierarchical manner and programmable features which are selected with functional mode buttons 42, selection buttons 44, and data wheel 46.

The functional mode buttons 42 and selection buttons 44 may be fixed or programmed as select keys, sample stop key, sample play key, sample record key, utility key, tuner key, sync/tap key, effects key, amp key, tempo key, drums key, auxiliary key, save key, and exit key. Data wheel 46 rotates in both directions to changes values and options within the various menus. For example, data wheel 46 can be rotated right or left to increase or decrease values within any particular settings.

In one embodiment, functional mode buttons 42 are assigned fixed features such as utility, tuner, and other global functions. The utility key allows the user to change settings to MIDI, playback, and recorded phrases and samples. The utility key also allows the user to perform system management functions like restoring factory presets, downloading new MIDI files and operating systems, and uploading and downloading presets. The tuner key places the amplifier into a fully chromatic tuner mode and changes the display to show a tuning meter such as shown in FIG. 5. The tuning meter shifts left and right as the user manually tunes each note of the musical instrument. The instrument is in-tune for the corresponding note when the tuning meter is centered or balanced.

Consider one example where the user wants to preset the equalizer settings. The user selects the utility key to display the utility options on LCD 40. The data wheel 46 rotates between the various options. In this mode, the selection keys 44 may be programmed for page up, page down, edit, and save. The user scrolls to the equalizer settings option and presses the edit key. The user is presented with the different frequency bands or ranges. Again, the user rotates data wheel 46 to change the equalizer values of each frequency band within the equalizer submenu. The save key allows the user to save the new settings.

The control panel 34 can also be used to configure and execute any one or combination of the following functions: digital guitar effects, equalization, filters, phrase training, phrase recording, phrase sampler, chromatic tuner, play loops, variable speed playback, sound selection, style selection, and restore factory settings. The user can download MIDI files and presets and store such data in internal memory in audio sound system 20 for future use by way of control panel 34.

Accordingly, the front panel control of audio sound system 20 provides a full-feature, multi-functional, integrated guitar entertainment center. The front panel provides controls for audio amplification of guitar 12, synthesizing a myriad of accompanying instruments such as electric guitar, violin, horns, brass, drums, wind instruments, string instruments, electric keyboard, audio microphone, percussions, or other instrument generating electric signals representative of sound content. The internal synthesizer of audio sound system 20 uses digital signal processing (DSP) technology to produce multiple sounds simultaneously. Audio sound system 20 is a virtual band to support guitar 12, fully integrated in a portable unit for the enjoyment of listeners. Audio sound system 20 is ideal for solo practice, private settings, and entertainment for small gatherings.

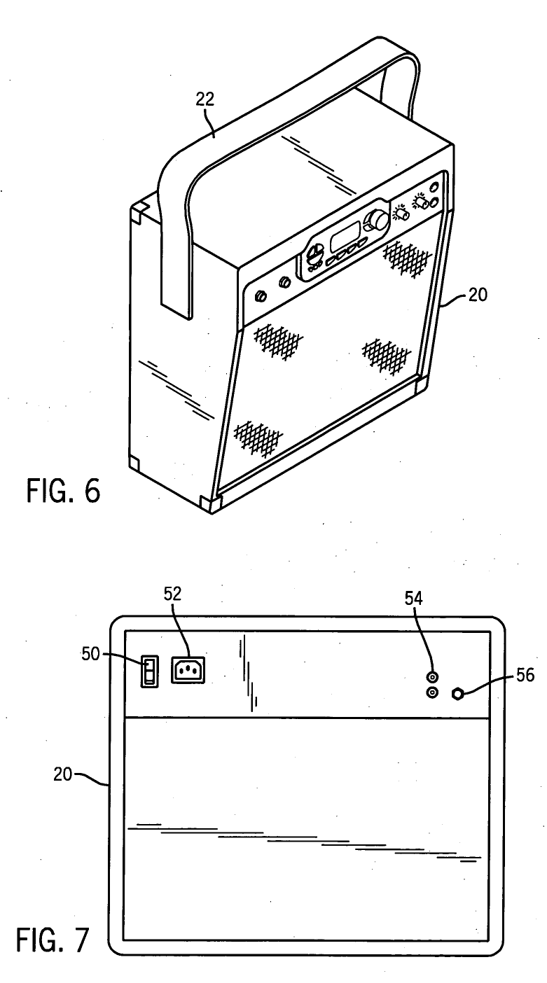

FIG. 6 illustrates a prospective view of audio sound system 20. The relative thin form factor and uniform aspect ratio gives audio sound system 20 its lightweight, stable, portability, and transportability characteristics.

FIG. 7 shows the back panel of audio sound system 20. Power switch 50 turns the unit on and off. Receptacle 52 receives the power cord. RCA jacks 54 can receive sound signals from an external source such as a CD player and send sound signals to external recorders. Auxiliary input 56 provides another audio input jack.

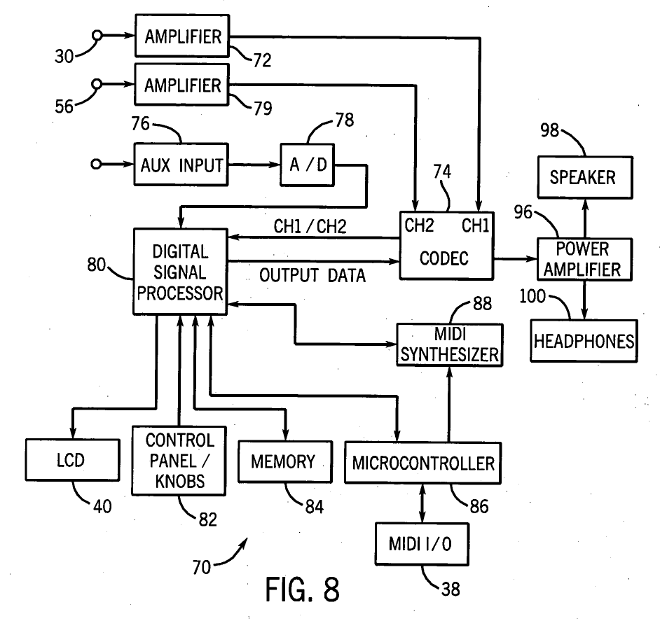

The electronic portion of audio sound system 20 is shown in FIG. 8 as an electrical block diagram 70. Audio input jack 30 is coupled to the input of amplifier 72. The output of amplifier 72 is coupled to channel (CH) 1 of coder/decoder (codec) block 74. Audio input jack 56 is coupled to the input of amplifier 79. The output of amplifier 79 is coupled to channel (CH) 2 of codec block 74. Alternatively, the audio input jacks may be routed through an A/D converter to an input of DSP 80. For example, analog signals received at aux input 76 are converted to digital signals by analog to digital (A/D) converter 78 and sent to DSP 80. The digitized audio signals from audio input jack 30 and 56 are routed by way of on CH1/CH2 link to DSP 80. Codec block 74 includes A/D converters and digital to analog (D/A) converters for the necessary conversions.

DSP 80 executes the software to perform the various configuration and signal processing functions of audio sound system 20. DSP 80 combines and mixes the digital audio signals from the various inputs using signal processing techniques understood by one skilled in the art. The software determines the menu options on LCD 40 and programs the functions imparted to the control panel selection keys 44. DSP 80 further drives LCD 40 on the front panel. Control panel/knobs 82 corresponds to control panel 34 and control knobs 36 on the front panel of audio sound system 20. Control panel/knobs 82 provides the user interface to audio sound system 20. DSP 80 accesses memory 84 to store software, settings, MIDI files, and sampled audio. Memory 84 may be implemented as one or more storage devices such as random access memory (RAM), read only memory (ROM), electrically programmable memory (EPROM), removable memory devices, and magnetic storage, e.g., hard disk.

Audio sound system 20 sends and receives MIDI data via MIDI I/O jacks 38 as provided on the front panel. The MIDI can be received from a personal computer (PC), keyboard, or any other device which transmits a MIDI data stream. MIDI communication protocol provides a data stream according to industry standards which allows for synthesis of virtually any sound. MIDI data is used with electronic devices such as DSP 80 or other synthesizer to generate musical instruments such as drums, guitar, horns, keyboard, tambourines, organs, wind instruments, and string instruments. MIDI data can also synthesize vocals and natural sounds.

MIDI I/O jacks 38 send and receive data through general purpose microcontroller 86. Microcontroller 86 routes MIDI data to DSP 80 or to MIDI synthesizer 88. Microcontroller 86 also receives MIDI data from DSP 80 for external access and storage. Microcontroller 86 controls the overall flow of MIDI data. The MIDI data may be sent to DSP 80 for further processing or storage in memory 84. DSP 80 can also route the MIDI data from internal sources, e.g. memory 84, to MIDI synthesizer 88.

MIDI synthesizer 88 processes the MIDI data to generate the programmed sounds. In one embodiment, MIDI synthesizer 88 is implemented as Atmel Part No. ATSAM3308 MIDI-Synthesizer (Dream Chip). The MIDI data may be used to synthesize virtually any tune, melody, song, or individual instrumental number. For example, the MIDI data can be used to synthesize any combination of drums, guitar, horns, keyboard, tambourines, organs, wind instruments, and string instruments. The synthesized audio from MIDI synthesizer 88 is routed to DSP 80. DSP 80 combines the synthesized audio with the digitized audio signals received via CH1/CH2, or A/D converter 78, and outputs the composite OUTPUT DATA signal to codex block 74.

The analog output of codec block 74 is amplified by power amplifier 94 and applied to speaker 98, which is integrated with the cabinet of audio sound system 20. In one embodiment, speaker 98 is 8 inches in diameter and is driven with up to 15 watts of power. The amplified analog output is also available to headphone jack 32 on the front panel of audio sound system 20 to drive headphones 100.

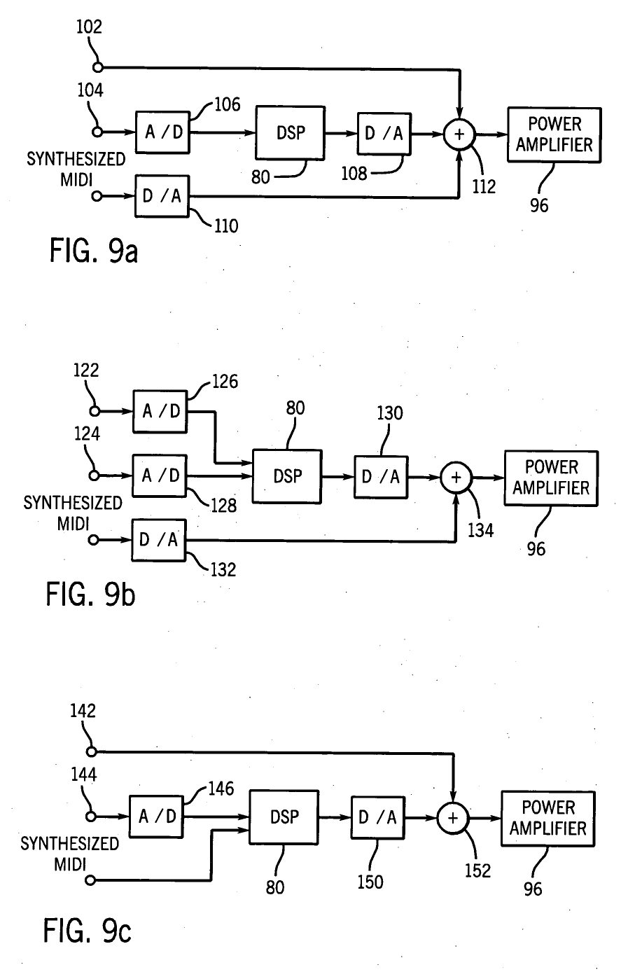

FIG. 9a illustrates a first representative configuration of electrical block diagram 70. Analog audio signals are received at terminals 102 and 104. The audio signal on terminal 104 is converted to a digital audio signal by A/D converter 106, processed in DSP 80, and converted back to analog audio signal by D/A converter 108. The synthesized MIDI signals are converted to analog audio signals by D/A 110. The analog signals are summed in audio summing junction 112 and routed to power amplifier 96.

FIG. 9b illustrates a second representative configuration of electrical block diagram 70. Analog audio signals are received at terminals 122 and 124. The audio signals are converted to digital audio signals by A/D converters 126 and 128, processed in DSP 80, and converted back to an analog audio signal by D/A converter 130. The synthesized MIDI signals are converted to analog audio signals by D/A 132. The analog signals are summed in audio summing junction 134 and routed to power amplifier 96.

FIG. 9c illustrates a third representative configuration of electrical block diagram 70. Analog audio signals are received at terminals 142 and 144. The audio signal on terminal 142 is converted to a digital audio signal by A/D converter 146 and routed to DSP 80. The synthesized MIDI signals in digital form are also sent in DSP 80. The DSP-processed signals are converted back to an analog audio signal by D/A converter 150. The analog signals are summed in summing junction 152 and routed to power amplifier 96.

Audio sound system 20 operates as a portable, fully integrated, multi-functional guitar entertainment center. The user can connect a musical instrument, such as an electric guitar or keyboard, to audio input jack 30 and play music in many situations. Audio sound system 20 can be programmed by the user through control panel 34 to generate virtual any other audio sound to accompany the user's instrument.

Audio sound system 20 has applications and uses for the youth market, as a learning and teaching tool, and in small gatherings such as a rally. A teaching professional can plug into the auxiliary input jack 56 and interactive play using the same amplifier and speaker system. The student can hear the instructor and repeat the same chords. Yet, audio sound system 20 has its own learning function. A teaching MIDI file can be fed into MIDI I/O 38. The student listens to MIDI synthesizer 88 generates the chords and then attempts to repeat the same sound.

Audio sound system 20 allows the user to operate as a one-man band. The MIDI data files for the accompanying instruments, e.g., drums, bass guitar, keyboard, are routed from an external source such as a PC through microcontroller 86 and DSP 80 and stored in memory 84. Upon command, DSP 80 retrieves the MIDI files and sends the data stream to MIDI synthesizer 88 which generates the desired accompaniments. Alternatively, the MIDI files can be provided from an internal source, e.g. memory 84. DSP 80 combines the user's instrument with the synthesized audio. The composite audio is output speaker 98 or headphones 100. The user plays his or her own instrument live while audio sound system 20 synthesizes all other instruments for a complete listening experience.

Audio sound system 20 also functions as an amplifier, equalizer, fully chromatic tuner, phrase sampler, phrase trainer, and equalizer in order to configure and execute play loops, MIDI files, variable speed playback, sample recording, sound selection, and style selection. The user can change speed and/or pitch of the MIDI files to learn to play certain difficult passages. Audio sound system 20 provides play loops, external loops, on-board effects, and sound presets. Audio sound system 20 may also have a vocal input jack for voice.

While one or more embodiments of the present invention have been illustrated in detail, the skilled artisan will appreciate that modifications and adaptations to those embodiments may be made without departing from the scope of the present invention as set forth in the following claims.

What is claimed is:

1. An audio sound system, comprising:
an enclosure for providing structural support;
a control panel with a display on a front portion of the enclosure;
an audio input coupled for receiving a live audio signal;
an electronic circuit disposed within the enclosure and receiving user commands from the control panel and displaying configuration information on the display, the electronic circuit including,
(a) an amplifier for amplifying the live audio signal, and
(b) a synthesizer for generating a programmable audio signal in response to a data stream; and
a speaker mounted within the enclosure and coupled for receiving a combined signal of the live audio signal and the programmable audio signal.

2. The audio sound system of claim 1, wherein the electronic circuit includes a digital signal processor coupled to the synthesizer for signal processing and controlling menu options on the display.

3. The audio sound system of claim 2, wherein the electronic circuit further includes a data input coupled for receiving the data stream which is routed to the digital signal processor or to the synthesizer.

4. The audio sound system of claim 3, wherein the data stream is organized according to a musical instrument digital interface (MIDI) standard.

5. The audio sound system of claim 1, further including a musical instrument having a sound output coupled to the audio input of the audio system.

6. The audio sound system of claim 5, wherein the musical instrument is selected from a group consisting of a string instrument, brass, woodwind, percussions, or keyboard.

7. A transportable audio sound system, comprising:
an enclosure for providing structural support;
a control panel disposed on a portion of the enclosure;
an audio input coupled for receiving an audio signal;
an electronic circuit receiving commands from the control panel, the electronic circuit including,
(a) an amplifier for amplifying the audio signal, and
(b) a synthesizer for generating a programmable audio signal in response to a data stream; and
a speaker mounted within the enclosure and coupled for receiving the audio signal and the programmable audio signal.

8. The transportable audio sound system of claim 7, further including a display disposed on the control panel.

9. The transportable audio sound system of claim 7, wherein the electronic circuit includes a digital signal processor coupled to the synthesizer.

10. The transportable audio sound system of claim 9, wherein the electronic circuit further includes a data input coupled for receiving the data stream which is routed to the digital signal processor or to the synthesizer.

11. The transportable audio sound system of claim 10, wherein the data stream is organized according to a musical instrument digital interface (MIDI) standard.

12. The transportable audio sound system of claim 7, wherein the electronic circuit provides at least one feature selected from the group consisting of equalizer, fully chromatic tuner, phrase sampler, phrase trainer, play loops, MIDI files, variable speed playback, sample recording, sound selection, and style selection.

13. The transportable audio sound system of claim 7, further including a strap attached to the enclosure for transporting the audio sound system.

14. An audio sound system, comprising:
an enclosure having a control panel and an audio input coupled for receiving an audio signal;
an amplifier for amplifying the audio signal;
a synthesizer for generating a programmable audio signal in response to a data stream; and
a speaker mounted within the enclosure and coupled for receiving the audio signal or the programmable audio signal.

15. The audio sound system of claim 14, further including a display disposed on the control panel.

16. The audio sound system of claim 14, wherein the data stream is organized according to a musical instrument digital interface (MIDI) standard.

17. The audio sound system of claim 14, further including a digital signal processor coupled to the synthesizer for signal processing and controlling menu options.

18. The audio sound system of claim 17, wherein the digital signal processor provides at least one feature selected from the group consisting of equalizer, fully chromatic tuner, phrase sampler, phrase trainer, play loops, MIDI files, variable speed playback, sample recording, sound selection, and style selection.

19. The audio sound system of claim 14, further including a strap attached to the enclosure for transporting the audio sound system.

20. A method of providing signal processing features for an audio sound system, comprising:
providing an enclosure having a control panel and an audio input coupled for receiving an audio signal;
amplifying the audio signal;
synthesizing a data stream to generate a programmable audio signal; and
providing a speaker mounted within the enclosure for receiving the audio signal or the programmable audio signal.

21. The method of claim 20, further including providing a display disposed on the control panel.

22. The method of claim 20, further including providing for selection of menu options which are presented on the display.

23. The method of claim 20, wherein the data stream is organized according to a musical instrument digital interface (MIDI) standard.

24. An audio sound system, comprising:
an enclosure having a control panel and an audio input coupled for receiving an audio signal;
a synthesizer within the enclosure for generating a programmable audio signal in response to a data stream; and
a digital signal processor within the enclosure providing at least one feature selected from the group consisting of equalizer, fully chromatic tuner, phrase sampler, phrase trainer, play loops, MIDI files, variable speed playback, sample recording, sound selection, and style selection; and
a speaker mounted within the enclosure and coupled for receiving the audio signal or the programmable audio signal.

25. The audio sound system of claim 24, further including a display disposed on the control panel.

26. The audio sound system of claim 24, wherein the data stream is organized according to a musical instrument digital interface (MIDI) standard.

27. The audio sound system of claim 24, further including a strap attached to the enclosure for transporting the audio sound system.
